(19) United States
(12) Patent Application Publication
(10) Pub. No.: US 2025/0386717 A1
(43) Pub. Date: Dec. 18, 2025

(54) DISPLAY PANEL AND DISPLAY DEVICE

(71) Applicants: Mianyang BOE Optoelectronics Technology Co., Ltd., Mianyang, Sichuan (CN); BOE Technology Group Co., Ltd., Beijing (CN)

(72) Inventors: Feng YANG, Beijing (CN); Fang ZHU, Beijing (CN); Lin YUE, Beijing (CN); Yunzhi WANG, Beijing (CN); Chunyan LI, Beijing (CN)

(73) Assignees: Mianyang BOE Optoelectronics Technology Co., Ltd., Mianyang, Sichuan (CN); BOE Technology Group Co., Ltd., Beijing (CN)

(21) Appl. No.: 19/126,653

(22) PCT Filed: Sep. 12, 2024
(86) PCT No.: PCT/CN2024/118456

§ 371 Date: May 2, 2025

(30) Foreign Application Priority Data
Oct. 30, 2023 (CN) 202311424573.2

(51) Int. Cl. H10K 59/80; H10K 59/38; H10K 102/00

(52) U.S. Cl. CPC H10K 59/879; H10K 59/38; H10K 59/8792; H10K 2102/351

(57) ABSTRACT

The present disclosure provides a display panel. The display substrate in the display panel includes a base substrate and a plurality of pixel units, wherein the base substrate includes an opening region, a transition region, a display region, and a peripheral region. The display panel further includes a first dimming layer and a second dimming layer. A refractive index of the first dimming layer is different from a refractive index of the second dimming layer. A portion of the second dimming layer within the transition region includes a plurality of first target regions, and thicknesses of portions of the second dimming layer within the plurality of first target regions are less than a thickness of a portion of the second dimming layer within the transition region other than within the plurality of first target regions.

### CROSS-REFERENCE TO RELATED APPLICATIONS

This application is a U.S. national stage of international application No. PCT/CN2024/118456, filed on Sep. 12, 2024, which claims priority to Chinese Patent Application No. 202311424573.2, filed on Oct. 30, 2023, entitled “DISPLAY PANEL AND DISPLAY DEVICE,” the disclosures of each are herein incorporated by reference in their entireties.

### TECHNICAL FIELD

The present disclosure relates to the field of display technologies, and in particular, relates to a display panel and a display device.

### BACKGROUND

A display panel includes a base substrate and a pixel unit disposed in a display region of the base substrate. The pixel unit is capable of emitting light, such that the display panel can achieve a display function.

### SUMMARY

Embodiments of the present disclosure provide a display panel and a display device. The technical solutions are as follows.

In one aspect, a display panel is provided. The display panel includes a display substrate; wherein the display substrate includes:
a base substrate, wherein the base substrate includes an opening region, a transition region surrounding the opening region, a display region surrounding the transition region, and a peripheral region surrounding the display region; and
a plurality of pixel units disposed on a side of the base substrate, wherein the plurality of pixel units are within the display region; and
the display panel further includes a first dimming layer and a second dimming layer that are disposed on a side, away from the base substrate, of the plurality of pixel units and stacked in sequence;
wherein the first dimming layer and the second dimming layer are disposed in the display region and the transition region, a refractive index of the first dimming layer is different from a refractive index of the second dimming layer, a portion of the second dimming layer within the transition region includes a plurality of first target regions, and thicknesses of portions of the second dimming layer within the plurality of first target regions are less than a thickness of a portion of the second dimming layer within the transition region other than within the plurality of first target regions.

In some embodiments, structures of the second dimming layer within the plurality of first target regions are grooves or through holes.

In some embodiments, an orthographic projection of each of the plurality of first target regions on the base substrate is annular, and surrounds the opening region; and
a gap is defined between any two adjacent first target regions of the plurality of first target

regions, wherein an orthographic projection of the gap on the base substrate is annular.

In some embodiments, an orthographic projection of each of the plurality of first target regions on the base substrate is bar-shaped, and each of the plurality of first target regions extends along an arrangement direction of the opening region and the transition region; and
the plurality of first target regions are evenly arranged around the opening region.

In some embodiments, the plurality of first target regions include: a plurality of first sub-regions and a plurality of second sub-regions; wherein the plurality of first sub-regions are closer to the opening region relative to the plurality of second sub-regions;
the plurality of second sub-regions are evenly and annularly arranged, and the plurality of second sub-regions are arranged in a direction such that orthographic projections of the plurality of second sub-regions on the base substrate surround the orthographic projections of the plurality of first sub-regions on the base substrate; and
the plurality of second sub-regions are evenly and annularly arranged, and the plurality of second sub-regions are arranged in a direction such that orthographic projections of the plurality of second sub-regions on the base substrate surround the orthographic projections of the plurality of first sub-regions on the base substrate; and
the plurality of first sub-regions are staggered with respect to the plurality of second sub-regions.

In some embodiments, the orthographic projections of the plurality of first sub-regions on the base substrate and the orthographic projections of the plurality of second sub-regions on the base substrate are shaped as trapezoids, circles, semicircles, arcs, triangles, rectangles, hexagons, or octagons.

In some embodiments, a plurality of first grooves are defined in a portion of the first dimming layer within the transition region, and at least a portion of the second dimming layer is disposed in the plurality of first grooves.

In some embodiments, the plurality of first grooves are in one-to-one correspondence with the plurality of first target regions, and an orthographic projection of each of the plurality of first grooves on the base substrate is overlapped with an orthographic projection of a corresponding first target region of the plurality of first target regions on the base substrate.

In some embodiments, the plurality of first grooves are staggered with respect to the plurality of first target regions.

In some embodiments, the display panel further includes a color filter layer disposed on a side, away from the base substrate, of the second dimming layer;
wherein the color filter layer includes a plurality of color filter blocks disposed in the display region, a plurality of dummy color filter blocks disposed in the transition region, and a black matrix disposed in the display region and the transition region;
wherein the black matrix includes a plurality of openings, each of the plurality of openings being configured to expose a corresponding color filter block of the plurality of color filter blocks, and an orthographic projection of each of the plurality of color filter blocks covering a luminous region of a corresponding pixel unit of the plurality of pixel units.

In some embodiments, structures of the second dimming layer within the plurality of first target regions are grooves or through holes; and
at least a portion of the black matrix within the transition region is disposed in the plurality of first target regions.

In some embodiments, the first dimming layer and the second dimming layer are further disposed in the peripheral region; and a portion of the second dimming layer within the peripheral region is provided with a plurality of second target regions, and thicknesses of portions of the second dimming layer within the plurality of second target regions are less than a thickness of a portion of the second dimming layer within the peripheral region other than within the plurality of second target regions.

In some embodiments, structures of the second dimming layer within the plurality of second target regions are grooves or through holes.

In some embodiments, a plurality of second grooves are defined in a portion of the first dimming layer within the peripheral region, and at least a portion of the second dimming layer is disposed in the plurality of second grooves.

In some embodiments, structures of the second dimming layer within the plurality of second target regions are grooves or through holes; and a black matrix in a color filter layer in the display panel is further disposed in the peripheral region;
wherein at least a portion of the black matrix within the peripheral region is disposed in the plurality of second target regions.

In some embodiments, the refractive index of the first dimming layer is less than the refractive index of the second dimming layer; and
a groove structure is defined in a surface, away from the display substrate, of a portion of the first dimming layer within the display region, wherein an angle between an extended surface of a side surface of the groove structure and a bearing surface of the base substrate is an acute angle or an obtuse angle, and a side wall of the groove structure is configured to converge light rays.

In some embodiments, an orthographic projection of the groove structure on the display substrate is within non-luminous regions of the plurality of pixel units; and a depth of the groove structure is less than a thickness of the first dimming layer;
a raised structure is defined on a surface, away from the display substrate, of a portion of the first dimming layer within the display region, an orthographic projection of the raised structure on the display substrate being within luminous regions of the plurality of pixel units; and
the side surface of the groove structure is an interface between the groove structure and the raised structure.

In some embodiments, an orthographic projection of the groove structure on the display substrate is within non-luminous regions of the plurality of pixel units; a depth of the groove structure is less than a thickness of the first dimming layer;
the first dimming layer includes a plurality of dimming structures spaced apart, orthographic projections of the plurality of dimming structures on the display substrate being within the luminous regions of the plurality of pixel units; and
the side surface of the groove structure is an interface between the groove structure and any of the plurality of dimming structures.

In some embodiments, an orthographic projection of the groove structure on the display substrate is within luminous regions of the plurality of pixel units; and a depth of the groove structure is less than or equal to a thickness of the first dimming layer.

In another aspect, a display device is provided. The display device includes a power supply assembly and the display panel as described in the above aspects;
wherein the power supply assembly is configured to supply power to the display panel.

### BRIEF DESCRIPTION OF DRAWINGS

For clearer descriptions of the technical solutions according to the embodiments of the present application, the following briefly introduces the accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a schematic structural diagram of a display panel according to some embodiments of the present disclosure;

FIG. 2 is a top view of a base substrate according to some embodiments of the present disclosure;

FIG. 3 is a schematic structural diagram of another display panel according to some embodiments of the present disclosure;

FIG. 4 is a partial schematic diagram of a second dimming layer according to some embodiments of the present disclosure;

FIG. 5 is a partial schematic diagram of another second dimming layer according to some embodiments of the present disclosure;

FIG. 6 is a partial schematic diagram of yet another second dimming layer according to some embodiments of the present disclosure;

FIG. 7 is a schematic structural diagram of yet another display panel according to some embodiments of the present disclosure;

FIG. 8 is a schematic structural diagram of yet another display panel according to some embodiments of the present disclosure;

FIG. 9 is a schematic structural diagram of still another display panel according to some embodiments of the present disclosure;

FIG. 10 is a schematic structural diagram of yet another display panel according to some embodiments of the present disclosure;

FIG. 11 is a schematic structural diagram of yet another display panel according to some embodiments of the present disclosure;

FIG. 12 is a schematic structural diagram of yet another display panel according to some embodiments of the present disclosure;

FIG. 13 is a schematic structural diagram of yet another display panel according to some embodiments of the present disclosure;

FIG. 14 is a schematic structural diagram of yet another display panel according to some embodiments of the present disclosure;

FIG. 15 is a partial schematic diagram of a target film layer and a first organic functional layer according to some embodiments of the present disclosure;

FIG. 16 is a partial schematic diagram of a touch substrate according to some embodiments of the present disclosure;

FIG. 17 is a schematic structural diagram of yet another display panel according to some embodiments of the present disclosure;

FIG. 18 is a schematic structural diagram of yet another display panel according to some embodiments of the present disclosure; and

FIG. 19 is a schematic structural diagram of a display device according to some embodiments of the present disclosure.

### DETAILED DESCRIPTION

For clearer descriptions of the objectives, technical solutions, and advantages of the present disclosure, the embodiments of the present disclosure are further described hereinafter with reference to the accompanying drawings.

In the related arts, the display panel further includes a dimming layer disposed in a display region. The dimming layer is configured to converge the light from the edge region of the pixel unit, such that the positive light-exiting amount of the pixel unit is increased.

However, the dimming layer is prone to warping during the preparation of subsequent film layers and in turn possibly pulls the other film layers in the display panel, thereby resulting in peeling of film layers in the display panel and a lower yield of the display panel.

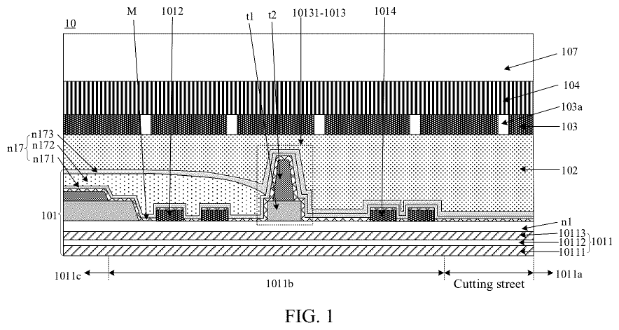

FIG. 1 is a schematic structural diagram of a display panel according to some embodiments of the present disclosure. Referring to FIG. 1 and FIG. 10, the display panel 10 includes: a display substrate 101, a first dimming layer 102, and a second dimming layer 103. The display substrate 101 includes: a base substrate 1011 and a plurality of pixel units 1016.

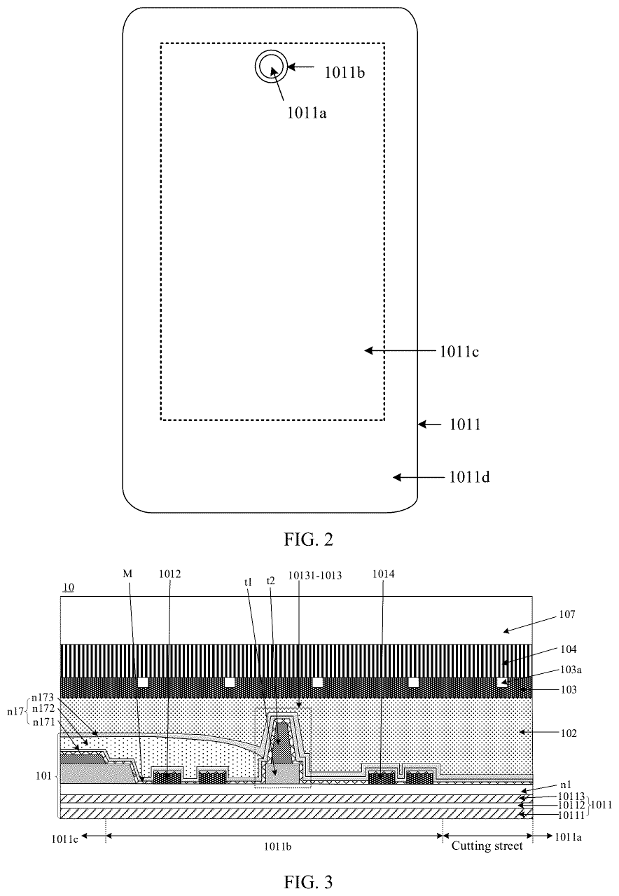

FIG. 2 is a top view of a base substrate according to some embodiments of the present disclosure. Combining FIGS. 1 and 2, the base substrate 1011 includes an opening region 1011a, a transition region 1011b surrounding the opening region 1011a, a display region 1011c surrounding the transition region 1011b, and a peripheral region 1011d surrounding the display region 1011c.

The plurality of pixel units 1016 are disposed on a side of the base substrate 1011 and are disposed in the display region 1011c. The plurality of pixel units 1016 are capable of emitting light, such that the display panel 10 achieves the display function. The first dimming layer 102 and the second dimming layer 103 are disposed on a side, away from the base substrate 1011, of the plurality of pixel units 1016 and are sequentially stacked in a direction away from the base substrate 1011. The first dimming layer 102 and the second dimming layer 103 are disposed in the display region 1011c and the transition region 1011b, and portions of the first dimming layer 102 and the second dimming layer 103 within the display region 1011c are capable of dimming the light rays emitted by the pixel units 1016, to increase the light-exiting amount of the pixel units 1016, increase the luminous intensity of the display panel 10, and improve the display effect. In some embodiments, materials of both the first dimming layer 102 and the second dimming layer 103 are optically clear adhesive (OC).

In some embodiments, a refractive index of the first dimming layer 102 is different from a refractive index of the second dimming layer 103. In the display region 1011c, light rays from the edge region of the pixel unit 1016 are refracted, when irradiated to the interface of the first dimming layer 102 and the second dimming layer 103, with a refraction direction closer to a target direction (the target direction is perpendicular to a bearing surface of the base substrate 1011) relative to an incident direction. That is, the first dimming layer 102 and the second dimming layer 103 are capable of converging the light rays from the edge region of the pixel unit 1016, such that the positive light-exiting amount of the pixel unit 1016 is increased.

In the case that the second dimming layer 103 is formed during the entire preparation process of the display panel, the entire structure possibly needs to be treated in a high temperature or high humidity environment to subsequently prepare the other film layers. In some embodiments, the high temperature means a temperature above 85° C., and the high humidity means a humidity above 85%. Further, due to the special nature of the material of the second dimming layer 103, the physical properties of the second dimming layer 103 possibly change (e.g., expansion) in the high temperature or high humidity environment, which in turn possibly results in warping of the display panel. In some embodiments, the material of the second dimming layer 103 is organic resin with added zirconia particles.

Typically, in the case that the display panel warps, the film layers in the display panel likely separate from each other (peeling). Moreover, in the case that the film layers peel from each other, water vapor or oxygen easily invades the display region 1011c along the surfaces of the peeled film layers, thereby resulting in dark spots in a hole (growing dark spots at the edge of the hole, GDSH) in the display region 1011c of the display panel 10 and a poorer display effect or even scrapping of the product in serious cases. Further, because the portions of the film layers in the display substrate 101 within the transition region 1011b near the opening region 1011a are more likely peels in the case where the physical properties of the second dimming layer 103 changes, and the sidewall of the opening region 1011a is exposed to the outside, water vapor and oxygen are more likely to invade into the display region 1011c from the sidewall of the opening region 1011a through the transition region 1011b. Thus, to ensure the display effect of the display panel 10, the portion of the second dimming layer 103 within the transition region 1011b needs to be specially designed to avoid warping of the display panel 10 and thus avoid the invasion of water vapor and oxygen due to the peeling of the film layers.

In some embodiments of the present disclosure, the portion of the second dimming layer 103 within the transition region 1011b includes a plurality of first target regions 103a, and thicknesses of portions of the second dimming layer 103 within the first target regions 103a are less than a thickness of a portion of the second dimming layer 103 within the transition region 1011b other than within the first target regions 103a.

During the subsequent high temperature or high humidity process for forming the display panel 10, because the thickness of the portion of the second dimming layer 103 within the first target region 103a is smaller, an expansion space is provided for the expansion of the material of the second dimming layer 103 to provide a stress guide or cushion for the second dimming layer 103 and accommodate a portion of the expansion amount of the second dimming layer 103, therefore, the total expansion amount of the second dimming is reduced to avoid the expansion amount of the second dimming layer 103 from being too large, thereby reducing the possibility of warping of the display panel, reducing the possibility of peeling of the film layers in the display panel, and improving the yield of the display panel.

In summary, the embodiments of the present disclosure provide a display panel. A display substrate in the display panel includes a base substrate, a plurality of pixel units, a first dimming layer, and a second dimming layer. The refractive index of the first dimming layer is different from the refractive index of the second dimming layer, such that the light rays emitted by the pixel units are converged, a positive light-exiting amount of the pixel unit is increased, and the display effect of the display panel is improved. Further, because a thickness of a portion, within the first target region, of the second dimming layer within the transition region is small, an expansion space is provided for the expansion of the material of the second dimming layer, such that the total expansion amount of the second dimming layer is reduced. As a result, the case of the expansion amount of the second dimming layer being too large is avoided, the warping possibility of the display panel and the peeling possibility of the film layers in the display panel are decreased, and the yield of the display panel is improved.

In some embodiments, referring to FIG. 1, structures of the second dimming layer 103 within the first target regions 103a are through holes. Alternatively, referring to FIG. 2, the structures of the second dimming layer 103 within the first target regions 103a are grooves.

For a straight type display panel (non-folding type), the structure of the second dimming layer 103 within the first target region 103a is a through hole or a groove, as long as the first target region 103a provides sufficient expansion space for the second dimming layer 103.

For a foldable display panel, during the folding of the foldable display panel, interlayer slippage or misalignment among the film layers likely occurs, which results in low stability. In the case that the structure of the second dimming layer 103 within the first target region 103a is a through hole, a slippage or misalignment amount among the film layers is possibly larger. Therefore, the structure of the second dimming layer 103 within the first target region 103a is a groove in the case where the display panel is foldable. A depth of the groove is flexibly adjusted according to the needs of different products.

In some embodiments of the present disclosure, for any foldable display panel, a fixed value is selected as the depth of the groove in the second dimming layer 103, and a performance test is subsequently conducted on the foldable display panel. In the case that all performances of the foldable display panel meet the factory requirements, the fixed value is directly used as the depth of the groove in the second dimming layer 103 of the foldable display panel. In the case that the slippage or misalignment amount of the foldable display panel during the folding process fails to meet the slippage or misalignment amount requirement, the fixed value is appropriately reduced and then used as the depth of the groove of the second dimming layer 103 in the foldable display panel. In the case that the warping amount of the foldable display panel is too large due to insufficient expansion space of the second dimming layer 103, the fixed value is appropriately increased and then used as the depth of the groove of the second dimming layer 103 in the foldable display panel. In some embodiments, the thickness of the second dimming layer 103 is 5 μm (micrometers), and the fixed value is half of the thickness of the second dimming layer 103, i.e., the fixed value is 2.5 μm.

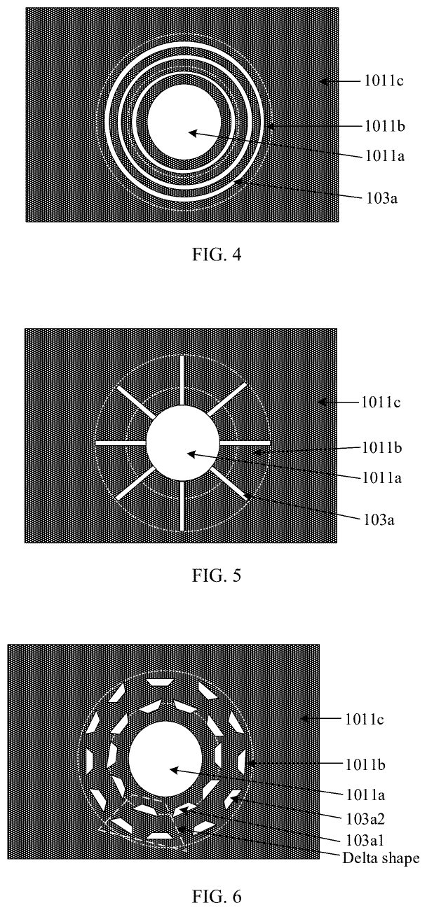

In some embodiments, referring to FIG. 4, an orthographic projection of each of the plurality of first target regions 103a on the base substrate 1011 is annular, and the orthographic projection of the first target region 103a on the base substrate 1011 surrounds the opening region 1011a. Referring to FIG. 4, a gap is defined between any two adjacent first target regions 103a of the plurality of first target regions 103a, and an orthographic projection of the gap on the base substrate 1011 is annular. That is, the plurality of first target regions 103a provided in the portion of the second dimming layer 103 within the transition region 1011b are sequentially nested.

In some embodiments, referring to FIG. 4, the portion of the second dimming layer 103 within the transition region 1011b includes three first target regions 103a, and the three first target regions 103a are sequentially nested. Of course, the portion of the second dimming layer 103 within the transition region 1011b has other numbers of first target regions 103a in some other embodiments, which is not limited in the embodiments of the present disclosure.

In some embodiments, a width of the first target region 103a ranges from 10 μm to 20 μm. Because a larger width of the first target region 103a likely results in a risk of air bubbles during the subsequent attachment of the polarizing layer, the width is 10 μm in some embodiments. Furthermore, a distance between adjacent first target regions 103a ranges from 50 μm to 80 μm in some embodiments. In some embodiments, taking the peeling risk of the film layers and stress release needs into account, the distance is set to be 50 μm, 55 μm, or the like. Moreover, the plurality of first target regions 103a are evenly arranged, and the number of the first target regions is greater than or equal to 3 in some embodiments.

In other embodiments, referring to FIG. 5, the orthographic projection of each first target region 103a on the base substrate 1011 is bar-shaped, and each first target region 103a extends along an arrangement direction of the opening region 1011a and the transition region 1011b. Therein, the plurality of first target regions 103a are evenly arranged around the opening region. In some embodiments, in FIG. 5, the portion of the second dimming layer 103 within the transition region 1011b includes eight first target regions 103a.

In some embodiments, the width of the first target region 103a ranges from 10 μm to 20 μm. Because a larger width of the first target region 103a is more likely to result in a risk of air bubbles during subsequent attachment of the polarizing layer, the width is 10 μm in some embodiments. In some embodiments, the plurality of first target regions 103a are distributed in a grid-like pattern including both vertical/horizontal and diagonal alignments. In other words, an angle between extension lines of any two adjacent first target regions 103a is 45°, and the number of first target regions 103a is preferably 8, but of course, the number is adjusted according to the actual need in some embodiments, such as 6.

In other embodiments, referring to FIG. 6, the plurality of first target regions 103a includes: a plurality of first sub-regions 103a1 and a plurality of second sub-regions 103a2. The plurality of first sub-regions 103a1 are closer to the opening region 1011a relative to the plurality of second sub-regions 103a2. In some embodiments, the plurality of first sub-regions 103a1 are referred to as an inner ring region, and the plurality of second sub-regions 103a are referred to as an outer ring region.

The plurality of first sub-regions 103a1 are evenly and annularly arranged, and the plurality of first sub-regions 103a1 are arranged in a direction such that orthographic projections of the plurality of first sub-regions 103a1 on the base substrate 1011 surround the opening region 1011a. The plurality of second sub-regions 103a2 are evenly and annularly arranged, and the plurality of second sub-regions 103a2 are arranged in a direction such that orthographic projections of the plurality of second sub-regions 103a2 on the base substrate 1011 surround the orthographic projections of the plurality of first sub-regions 103a1 on the base substrate 1011. The plurality of first sub-regions 103a1 are staggered with respect to the plurality of second sub-regions 103a2.

In some embodiments, referring to FIG. 6, the orthographic projection of the first sub-region 103a1 on the base substrate 1011 and the orthographic projection of the second sub-region 103a2 on the base substrate 1011 are shaped as trapezoids. Moreover, an upper base of the trapezoid is closer to the opening region 1011a relative to a lower base of the trapezoid. Of course, in some embodiments, the orthographic projection of the first sub-region 103a1 on the base substrate 1011 and the orthographic projection of the second sub-region 103a2 on the base substrate 1011 has other shapes, such as circles, semicircles, arcs, triangles, squares, rectangles, hexagons, octagons, or the like, which are not limited in the embodiments of the present disclosure.

In some embodiments, the plurality of second sub-regions 103a1 are arranged in an

equally spaced distribution manner according to a clock model including 12 hours, i.e., an angle of central axis extension lines of two adjacent second sub-regions 103a is 30°. Accordingly, the plurality of first sub-regions 103a1 are distributed in the same manner. Referring to FIG. 6, any first sub-region 103a1 (inner ring region) and two second sub-regions 103a2 (outer ring region) opposite to the first sub-region 103a1 form a delta shape. In some embodiments, for the sub-regions in the same ring, the distance between any two adjacent sub-regions ranges from 50 μm to 80 μm. In some embodiments, taking the peeling risk of the film layers and the stress release needs into account, the distance is set to be 50 μm, 55 μm, or the like.

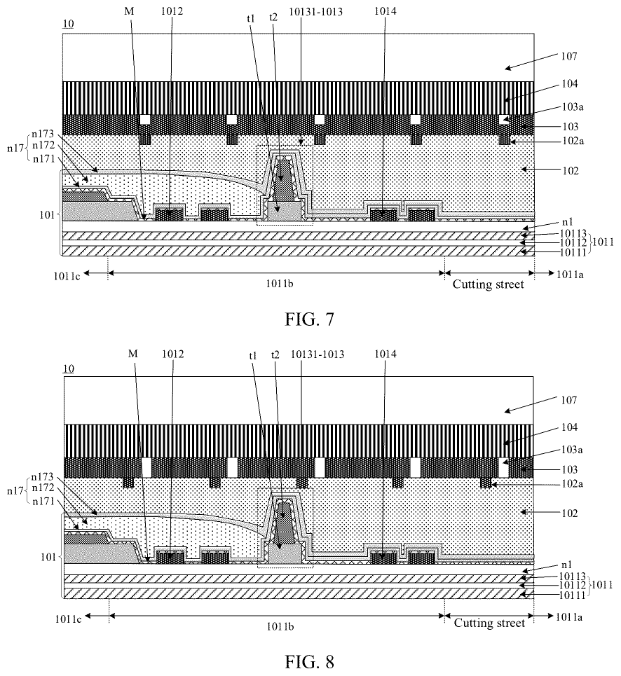

FIG. 7 is a schematic structural diagram of yet another display panel according to some embodiments of the present disclosure. Referring to FIG. 7, a plurality of first grooves 102a are defined in a portion of the first dimming layer 102 within the transition region 1011b, and at least a portion of the second dimming layer 103 is disposed in the plurality of first grooves 102a.

Because the first grooves 102a are defined in the portion of the first dimming layer 102 within the transition region 1011b and at least a portion of the second dimming layer 103 is disposed in the plurality of first grooves 102a, the portions of the second dimming layer 103 and the first dimming layer 102 within the transition region 1011b form a nested structure, which increases the contact area of the second dimming layer 103 and the first dimming layer 102, improves the bonding force of the second dimming layer 103 and the first dimming layer 102, and avoids the peeling of the first dimming layer 102 and the second dimming layer 103.

In some embodiments, the method for preparing the plurality of first grooves 102a on the first dimming layer 102 includes: forming a first dimming film; and acquiring the first dimming layer 102 by patterning the first dimming film using a first mask. The patterning process includes: coating a photoresist, exposing, developing, etching, and removing the photoresist. The depth of the first groove 102a on the first dimming layer 102 is controlled by controlling the etching duration of the etching process.

Alternatively, in some embodiments, the method for preparing the structures (groove or through hole) of the second dimming layer 103 within the first target regions 103a includes: forming a second dimming film; and acquiring the second dimming layer 103 by patterning the second dimming film using a second mask. The patterning process includes: coating a photoresist, exposing, developing, etching, and removing the photoresist. The depth of the structure of the second dimming layer 103 within the first target region 103a is controlled by controlling the etching duration of the etching process.

Referring to FIG. 7, the plurality of first grooves 102a are in one-to-one correspondence with the plurality of first target regions 103a, and an orthographic projection of each first groove 102a on the base substrate 1011 is overlapped with an orthographic projection of a corresponding first target region 103a on the base substrate 1011. In this case, the first mask used to form the plurality of first grooves 102a on the first dimming layer 102 and the second mask used to form the plurality of first target regions 103a on the second dimming layer 103 are the same.

Referring to FIG. 8, the plurality of first grooves 102a are staggered with respect to the

plurality of first target regions 103a. That is, the orthographic projection of each first groove 102a on the base substrate 1011 is not overlapped with the orthographic projection of any one of the plurality of first target regions 103a on the base substrate 1011. In this case, the first mask used to form the plurality of first grooves 102a on the first dimming layer 102 and the second mask used to form the plurality of first target regions 103a on the second dimming layer 103 are two different masks.

As can be seen from FIGS. 1, 3, 7, and 8, the display panel 10 further includes: a polarizer (POL) 104 (e.g., a circular polarizer) disposed on a side, away from the base substrate 1011, of the second dimming layer 103. The polarizer 104 is configured to change the polarization manner of light rays, to effectively prevent the interference of ambient light on the display brightness and contrast of the display panel.

To increase the transmittance of the display panel and make the display panel thinner, a solution in which the polarizer (POL) is avoided is adopted. In some embodiments, the solution is implemented by forming a color filter layer 105 (color filter on encapsulation, COE) on the upper side of the second dimming layer 103 in the display panel 10.

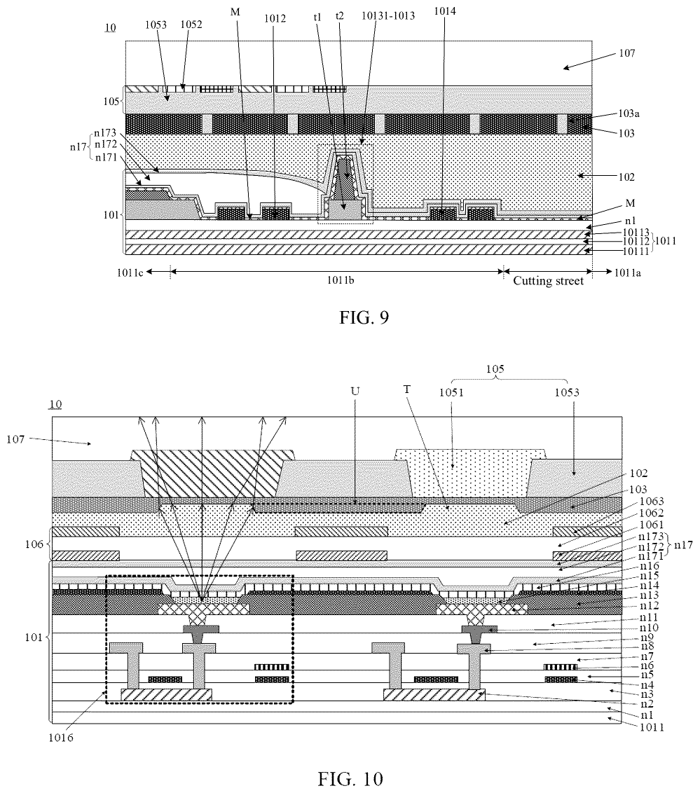

Referring to FIGS. 9 and 10, the display panel 10 further includes: a color filter layer 105 disposed on a side, away from the base substrate 1011, of the second dimming layer 103. The color filter layer 105 includes a plurality of color filter blocks 1051 disposed in the display region 1011c, a plurality of dummy color filter blocks 1052 disposed in the transition region 1011b, and a black matrix 1053 disposed in the display region 1011c and the transition region 1011b.

The black matrix 1053 includes a plurality of openings, each of the plurality of openings is configured to expose a corresponding color filter block 1051, and an orthographic projection of each color filter block 1051 on the base substrate 1011 covers a luminous region of a corresponding pixel unit 1016. Light rays emitted by the pixel unit 1016 exit upon passing through a corresponding color filter block 1051.

The dummy color filter blocks 1052 of the color filter layer 105 disposed in the transition region 1011b are provided to avoid the display effect of the display region 1011c from being impacted by the structure design changes between the display region 1011c and the transition region 1011b.

Referring to FIG. 9, at least a portion of the black matrix 1053 within the transition region 1011b is disposed in the plurality of first target regions 103a. That is, in some embodiments, the black matrix 1053 and the second dimming layer 103 form a nested structure to increase the contact area of the second dimming layer 103 and the black matrix 1053, thereby increasing the bonding force between the second dimming layer 103 and the black matrix 1053 and avoiding the peeling of the black matrix 1053 and the second dimming layer 103.

In some embodiments of the present disclosure, the first dimming layer 102 and the second dimming layer 103 are further disposed in the peripheral region 1011d. In the case that the physical properties of the second dimming layer 103 change, in addition to the portion, within the transition region 1011b, of the film layers of the display substrate 101, the portion, within the peripheral region 1011d of the film layers of the display substrate 101 also likely peels from each other. Therefore, water vapor and oxygen possibly invade the display region 1011c through the peripheral region 1011d. To this end, to ensure the display effect of the display panel 10, the portion, within the peripheral region 1011d, of the second dimming layer 103 needs to be specially designed.

In some embodiments of the present disclosure, referring to FIG. 11, the portion of the

second dimming layer 103 within the peripheral region 1011d is provided with a plurality of second target regions 103b, and thicknesses of portions of the second dimming layer 103 within the plurality of second target regions 103b are less than a thickness of a portion of the second dimming layer 103 within the peripheral region 1011d other than within the plurality of second target regions 103b.

In the subsequent high temperature or high humidity process for forming the display panel, because the thickness of the portion of the second dimming layer 103 within the second target region 103b is smaller, an expansion space is provided for the expansion of the material of the second dimming layer 103, and the expansion space provides a stress guide or cushion for the second dimming layer 103 and accommodates a part of the expansion amount of the second dimming layer 103, thereby reducing the total expansion amount of the second dimming layer 103, avoiding the case where the expansion amount of the second dimming layer 103 is too large, and thus reducing the warping possibility of the portion of the display panel 10 within the peripheral region 1011d, decreasing the peeling possibility of the film layers in the display panel 10, and improving the yield of the display panel 10.

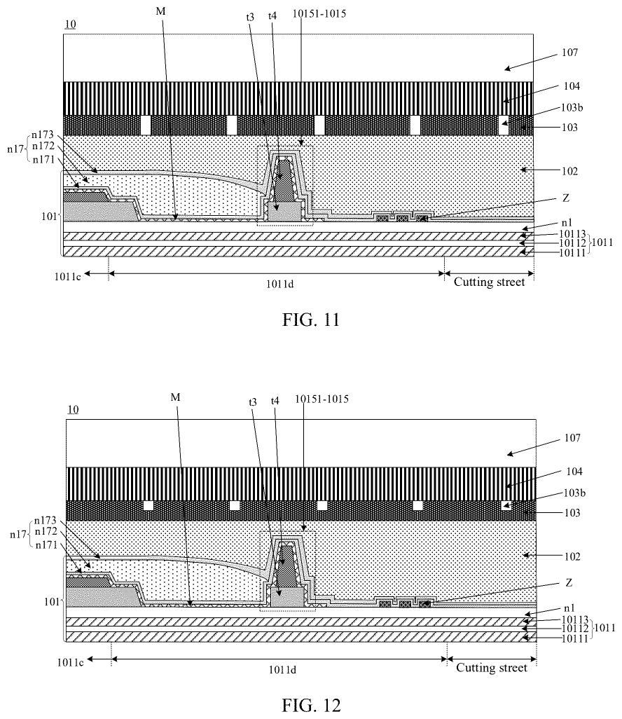

In some embodiments, referring to FIG. 11, the structure of the second dimming layer 103 within the second target region 103b is a through hole. Alternatively, referring to FIG. 12, the structure of the second dimming layer 103 within the second target region 103b is a groove.

For a straight type display panel (non-folding type), the structure of the second dimming layer 103 within the second target region 103b is a through hole or a groove, as long as the second target region 103b provides sufficient expansion space for the second dimming layer 103.

For a foldable display panel, during the folding of the foldable display panel, the slippage or misalignment amount among the film layers likely occurs, which results in low stability. In the case that the structure of the second dimming layer 103 within the second target region 103b is a through hole, the slippage or misalignment amount among the film layers is possibly larger. Therefore, the structure of the second dimming layer 103 within the second target region 103b is a groove in the case where the display panel is foldable. A depth of the groove is flexibly adjusted according to the needs of different products. More specific features of the second target region can refer to the above embodiments describing the first target region, which is not repeated in the embodiments of the present disclosure.

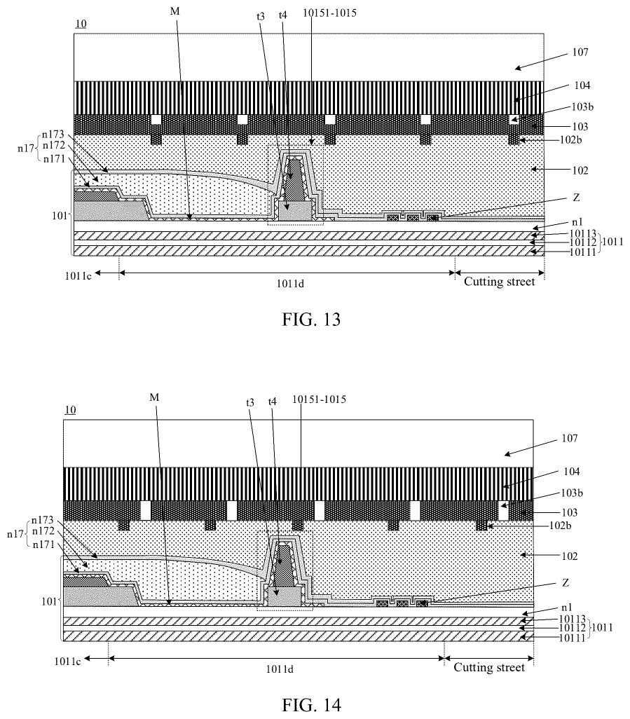

In some embodiments of the present disclosure, referring to FIG. 13, a plurality of second grooves 102b are defined in the portion of the first dimming layer 102 within the peripheral region 1011d, and at least a portion of the second dimming layer 103 is disposed in the plurality of second grooves 102b.

Because the second grooves 102b are defined in the portion of the first dimming layer 102 within the transition region 1011b and at least a portion of the second dimming layer 103 is disposed in the plurality of second grooves 102b, the portions of the second dimming layer 103 and the first dimming layer 102 within the transition region 1011b form a nested structure, which increases the contact area of the second dimming layer 103 and the first dimming layer 102, improves the bonding force of the second dimming layer 103 and the first dimming layer 102, and avoids the peeling of the first dimming layer 102 and the second dimming layer 103.

In some embodiments, referring to FIG. 13, the plurality of second grooves 102b are in one-to-one correspondence with the plurality of second target regions 103b, and an orthographic projection of each second groove 102b on the base substrate 1011 is overlapped with an orthographic projection of a corresponding second target region 103b on the base substrate 1011. Alternatively, referring to FIG. 14, the plurality of second grooves 102b are staggered with respect to the plurality of second target regions 103b.

With reference to FIGS. 11 to 14, it can be seen that the portion of the display substrate 101 within the peripheral region 1011d further includes a plurality of crack-blocking dams Z. The crack-blocking dams Z include a planarization pattern of a planarization layer of the display substrate 101. In some embodiments, the crack-blocking dams Z are formed during the formation of the planarization layer, and in some embodiments, are formed by performing a patterning process (photoresist coating, exposure, development, etching, and removal of photoresist) on a planarization film using a mask. In some embodiments, the crack-blocking dams Z include a plurality of strip-like structures independently provided, which are mainly configured for the following: in the event that a crack possibly extends toward the display region 1011a under an external force, the crack-blocking dam Z blocks the extension path of the crack, thereby protecting the display region 1011a.

Further, the black matrix 1053 in the color filter layer 105 is disposed in the peripheral region 1011d, and at least a portion of the black matrix 1053 within the peripheral region 1011d is disposed in a plurality of second target regions 103b. That is, the portions of the black matrix 1053 and the second dimming layer 103 within the peripheral region 1011d form a nested structure to increase the contact area of the second dimming layer 103 and the black matrix 1053, which in turn improves the bonding force between the second dimming layer 103 and the black matrix 1053 and avoids the peeling of the black matrix 1053 and the second dimming layer 103.

In some embodiments of the present disclosure, referring to FIG. 9, the display substrate 101 further includes: a first organic functional layer M disposed on a side of the base substrate 1011, wherein the first organic functional layer M is disposed in the display region 1011c and the transition region 1011b. The display substrate 101 further includes: a first isolation column 1012, a first barrier structure 1013, and a second isolation column 1014 that are disposed in the transition region 1011b and arranged in sequence along a direction away from the display region 1011c, wherein the first organic functional layer M is broken at one or more of the first isolation column 1012 and the second isolation column 1014.

It is noted that water vapor and oxygen tend to diffuse along the first organic functional layer M to the display region 1011c, and because the first organic functional layer M is broken at the position of at least one isolation column, even if the water vapor and oxygen enters the first organic functional layer M from the side of the opening region 1011a of display panel, the water vapor and oxygen are blocked outside the at least one isolation column from entering the display region 1011 along the first organic functional layer M. Further, in some embodiments, the first organic functional layer M is broken at both the first isolation column 1012 and the second isolation column 1014, such that water vapor and oxygen are further prevented from entering the display region 1011c. As a result, the pixel unit 1016 of the display substrate 101 within the display region 1011c is prevented from being corroded by the water vapor and oxygen, and thus the display effect is ensured.

In some embodiments of the present disclosure, the material of the first organic functional layer M is an organic material that easily absorbs water and oxygen, and thus water vapor and oxygen enter the display substrate 101 from the side of the opening region 1011a of the display substrate 101 through the first organic functional layer M. By making the first organic functional layer M to be broken at one or more of the first isolation column 1012 and the second isolation column 1014, water vapor and oxygen are prevented from entering the display region 1011c along the first organic functional layer M.

In some embodiments, both the first isolation column 1012 and the second isolation column 1014 are annular structures surrounding the opening region 1011a. The display substrate 101 includes a plurality of first isolation columns 1012 and a plurality of second isolation columns 1014. In some embodiments, as shown in FIG. 1, the display substrate 101 includes two first isolation columns 1012 and two second isolation columns 1014.

In some embodiments of the present disclosure, the display substrate 101 further includes: a second barrier structure 1015 disposed in the peripheral region 1011d. In some embodiments, the second barrier structure 1015 is configured to block an overflow of an organic material disposed in the display region 1011a.

In some embodiments of the present disclosure, referring to FIG. 10, the display substrate 101 includes: a buffer layer n1, an active layer n2, a first gate insulating layer (gate insulator, GI) n3, a first gate layer n4, a second gate insulating layer n5, a second gate layer n6, an interlevel dielectric layer (ILD) n7, a first source-drain layer n8, a planarization layer (PLN) n9, a second source-drain layer n10, a second planarization layer n11, an anode layer n12, a pixel definition layer (PDL) layer n13, a support layer (including such as photo spacer, PS) n14, a light-emitting film layer n15, a cathode layer n16, and a packaging layer n17 that are stacked in sequence in a direction away from the base substrate 1011.

The first gate layer n4, the second gate layer n6, the first source-drain layer n8, the first planarization layer n9, the second source-drain layer n10, and the second planarization layer n11 are disposed in the display region 1011c, and the first gate insulating layer n3, the second gate insulating layer n5, and the interlayer dielectric layer n7 are disposed in the transition region 1011b and the display region 1011c.

In some embodiments of the present disclosure, both the first isolation column 1012 and the second isolation column 1014 include a target film layer H. The target film layer His disposed in the first source-drain layer n8, and an orthographic projection of the target film layer H on a reference plane is I-shaped. By setting the target film layer H in the first isolation column 1012 and the second isolation column 1014 with an I-shape, the first organic functional layer M is easily broken at the first isolation column 1012 and the second isolation column 1014, which avoids the diffusion of water vapor and oxygen into the display region 1011c.

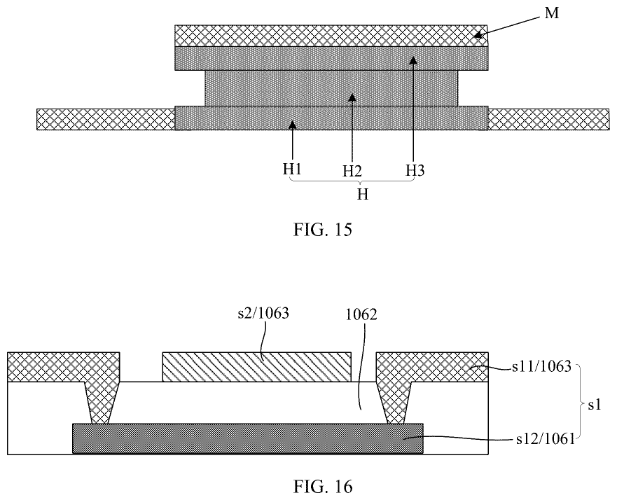

In some embodiments, referring to FIG. 15, the target film layer H includes a first metal layer H1, a second metal layer H2, and a third metal layer H3 stacked sequentially in a direction away from the base substrate 1011, wherein an etching rate of the second metal layer H2 is greater than etching rates of the first metal layer H1 and the third metal layer H3.

In some embodiments of the present disclosure, due to the larger etching rate of the second metal layer H2 and the smaller etching rates of the first metal layer H1 and the third metal layer H3, the target film layer H is made to be I-shaped based on the difference in the etching rates of the various metal layers.

In some embodiments, assuming that the target film layer H and the first source-drain layer n8 are in the same layer, because the first source-drain layer n8 is usually composed of triple layers of metal: laminated titanium (Ti), aluminum (Al), and titanium, the materials of the first metal layer H1 and the third metal layer H3 in the target film layer H are also titanium, and the material of the second metal layer H2 is aluminum.

In some embodiments of the present disclosure, the first isolation column 1012 and the second isolation column 1014 further include other film layers in addition to the target film layer H. In some embodiments, both the first isolation column 1012 and the second isolation column 1014 include a gate pattern disposed in the same layer as the first gate layer n4 and a gate pattern disposed in the same layer as the second gate layer n6.

In some embodiments of the present disclosure, the film layers included in different isolation columns of the display substrate 101 are different. Of course, the film layers included in different isolation columns of the display substrate 101 are the same in some embodiments, which is not limited in the embodiments of the present disclosure. Regardless of the film layers included in different isolation columns of the display substrate 101, it is sufficient to ensure that the first organic functional layer M is broken at one or more isolation columns in the display substrate 101.

In some embodiments of the present disclosure, each pixel unit 1016 in the display substrate 101 within the display region 1011c includes a pixel circuit and a light-emitting unit. In some embodiments, the pixel circuit includes a storage capacitor and at least one thin film transistor.

In some embodiments, the active layer n2 includes a plurality of active patterns. In some embodiments, the first gate layer n4 includes a plurality of first gate patterns. In some embodiments, the second gate layer n6 includes a plurality of second gate patterns. In some embodiments, the first source-drain layer n8 includes a plurality of source electrodes and a plurality of drain electrodes that are in one-to-one correspondence with the plurality of source electrodes. In some embodiments, the second source-drain layer n10 includes a plurality of connection patterns.

In some embodiments, one active pattern, one first gate pattern, one source electrode, and one drain electrode form a thin film transistor, and the source electrode and a corresponding drain electrode of each thin film transistor are connected to the active pattern. In some embodiments, one first gate pattern and one second gate pattern form a storage capacitor.

Referring to FIG. 10, the anode layer n12, the light-emitting film layer n15, and the cathode layer n16 included in the display substrate 101 form the light-emitting units of the plurality of pixel units 1016. In some embodiments, the anode layer n12 includes a plurality of anode patterns. In some embodiments, the light-emitting film layer n15 includes the first organic functional layer M, a second organic functional layer, and a light-emitting pattern (only the light-emitting pattern is shown in the drawings for representing the light-emitting film layer n15). The anode layer n12, the second organic functional layer, and the light-emitting pattern are all disposed in the display region 1011c, and the cathode layer n16 is disposed in the transition region 1011b and the display region 1011c.

In some embodiments, the anode layer n12, the second organic functional layer, and the light-emitting pattern being all disposed in the display region 1011c means: the anode layer n12, the second organic functional layer, and the light-emitting pattern are only disposed in the display region 1011c, and not in the transition region 1011b. In some embodiments, the first organic functional layer M at least includes a hole-transporting layer and an electron-transporting layer, and the second organic functional layer at least includes a hole-injection layer and an electron-injection layer.

Referring to FIG. 10, the pixel definition layer n13 in the display substrate 101 includes a plurality of cut-out regions, each of the cut-out regions is configured to expose an anode pattern of a pixel unit 1016. The anode pattern of each pixel unit 1016 is connected to a drain electrode of a thin film transistor via a connection pattern.

In some embodiments of the present disclosure, the packaging layer n17 includes a first inorganic packaging layer n171, an organic packaging layer n172, and a second inorganic packaging layer n173 stacked in sequence. Both the first inorganic packaging layer n171 and the second inorganic packaging layer n173 are disposed in the display region 1011c, the peripheral region 1011d, and the transition region 1011b, and the organic packaging layer n172 is disposed at a side, close to the display region 1011c, of the first barrier structure 1013.

In some embodiments, the material of the organic packaging layer n172 is an organic material, and the water vapor and oxygen are prevented from entering the display region 1011c from the organic packaging layer n172 by disposing the organic packaging layer n172 not in the peripheral region 1011d and the transition region, which at the same time ensures the packaging effect.

In some embodiments, the material of the first inorganic packaging layer n171 is silicon oxynitride (SiNO), and the material of the second inorganic packaging layer n173 is silicon nitride (SiN). The organic packaging layer n172 is made of a resin material. In some embodiments, the resin is a thermoplastic resin or a thermosetting resin, wherein the thermoplastic resin includes an acrylic (PMMA) resin, and the thermosetting resin includes an epoxy resin.

In some embodiments, the first inorganic packaging layer n171 and the second inorganic packaging layer n173 are formed through a chemical vapor deposition (CVD) process. The organic packaging layer n172 is formed using an ink jet printing (IJP) process.

In some embodiments of the present disclosure, referring to FIG. 1, the first barrier structure 1013 includes: a first barrier dam 10131. In some embodiments, the first barrier dam 10131 includes a first pattern t1 and a second pattern t2 sequentially stacked along a direction away from the base substrate 1011, wherein the first pattern t1 is disposed in the second planarization layer, and the second pattern t2 is disposed in the pixel definition layer n13.

Of course, in some embodiments, the first barrier structure 1013 includes a first barrier dam 10131 and a second barrier dam (not shown in the drawings) arranged along a direction close to the opening region 1011a. In some embodiments, a height of the first barrier dam 10131 and a height of the second barrier dam are equal. In some embodiments, both the first barrier dam 10131 and the second barrier dam include a pattern of the second planarization layer and a pattern of the pixel definition layer n13. Of course, in some embodiments, the height of the first barrier dam 10131 and the height of the second barrier dam are different, which is not limited in the embodiments of the present disclosure.

Referring to FIG. 11, in some embodiments, the second barrier structure 1015 includes: a third barrier dam 10151. In some embodiments, the third barrier dam 10151 includes a third pattern t3 and a fourth pattern t4 stacked sequentially along a direction away from the base substrate 1011. The third pattern t3 is disposed in the second planarization layer, and the fourth pattern t4 is disposed in the pixel definition layer n13.

Of course, in some embodiments, the second barrier structure 1015 includes a third barrier dam 10151 and a fourth barrier dam (not shown in the drawings) arrayed in a direction away from the display region 1011a. In some embodiments, the height of the third barrier dam 10151 is greater than a height of the fourth barrier dam. Of course, in some embodiments, the height of the third barrier dam 10151 is the same as the height of the fourth barrier dam, which is not limited in the embodiments of the present disclosure.

In some embodiments of the present disclosure, referring to FIG. 10, the display panel 10 further includes: a touch substrate 106 disposed in the display region 1011a. The touch substrate 106 includes a first touch electrode layer 1061, an insulating layer 1062, and a second touch electrode layer 1063 that are disposed at the light-exiting side of the display substrate 101 and stacked in sequence.

One of the first touch electrode layer 1061 and the second touch electrode layer 1063 includes a bridging electrode s12 of a plurality of first touch electrodes s1, and the other of the first touch electrode layer 1061 and the second touch electrode layer 1063 includes a body electrode s11 of the plurality of first touch electrodes s1 and a plurality of second touch electrodes s2. The bridging electrode and the body electrode are electrically connected via a through hole provided on the insulating layer 1062. In some embodiments, the material of the insulating layer 1062 is an organic material, which facilitates the bending of the display panel 10. Of course, the material of the insulating layer 1062 is an inorganic material in some embodiments.

In some embodiments, referring to FIG. 16, the bridging electrode of the plurality of first touch electrodes s1 is disposed in the first touch electrode layer 1061, and the body electrode s11 of the plurality of first touch electrodes s1 and the plurality of second touch electrodes s2 are disposed in the second touch electrode layer 1063. Alternatively, the body electrode s11 of the plurality of first touch electrodes s1 and the plurality of second touch electrodes s2 are disposed in the first touch electrode layer 1061, and the bridging electrode s12 of the plurality of first touch electrodes s1 are disposed in the second touch electrode layer 1063.

Further, in some embodiments, the touch substrate 106 includes: a drive circuit and a detection circuit disposed in the peripheral region 1011d. The drive circuit is electrically connected to the plurality of first touch electrodes s1 and configured to provide a drive signal to the first touch electrode s1. The detection circuit is electrically connected to the second touch electrode s2 and configured to detect an inductive signal, from the second touch electrode s2, between the first touch electrode s1 and the second touch electrode s2.

In the process of the drive circuit providing a drive signal for the first touch electrode s1, the detection circuit is capable of detecting the inductive signal, from the second touch electrode s2, between the first touch electrode s1 and the second touch electrode s2. In the case that the user's finger gets close to the display panel, the detection circuit 1025 is capable of detecting a change in the inductive signal at the position of the user's finger and determining the position at which the inductive signal has changed as the touch position.

In some embodiments, because the drive circuit is electrically connected to the first touch electrode s1, the first touch electrode s1 serves as a transmitting (TX) electrode. In some embodiments, because the detection circuit is electrically connected to the second touch electrode s2, the second touch electrode s2 serves as a receiving (RX) electrode.

In some embodiments of the present disclosure, referring to FIG. 10, the portion of the first dimming layer 102 within the display region 1011a covers an entire side, away from the display substrate, of the touch substrate 106, to protect the second touch electrode layer 1063 in the touch substrate 106.

Further, referring to FIG. 10, a groove structure U is provided on a surface, away from the display substrate 101, of the portion of the first dimming layer 102 within the display region 1011a. An angle between an extended surface of a side wall of the groove structure U and a bearing surface of the base substrate 1011 is an acute angle or an obtuse angle. That is, the extended surface of the side wall of the groove structure U is inclined with respect to the bearing surface of the base substrate 1011. By setting the refractive index of the first dimming layer 102 to be less than the refractive index of the second dimming layer 103, the side surface of the groove structure U is capable of refracting and converging light rays. That is, the light rays emitted by the pixel unit 1016 are converged upon being refracted at the side surface of the groove structure U.

Scheme 1, referring to FIG. 10, an orthographic projection of the groove structure U on the display substrate 101 is within a non-luminous region of the pixel unit 1016. A depth of the groove structure U is less than the thickness of the first dimming layer 102.

In the embodiments, a raised structure is defined on a surface, away from the display substrate, of the portion of the first dimming layer 102 within the display region 1011a. An orthographic projection of the raised structure T on the display substrate 101 is within the luminous region of the pixel unit 1016. In some embodiments, the side surface of the groove structure U is an interface between the groove structure U and the raised structure T.

Referring to FIG. 10, in some embodiments, the raised structure T is shaped as an approximate trapezoid, and the approximate trapezoid refers to a standard trapezoid or a non-standard trapezoid with a curved surface for process reasons.

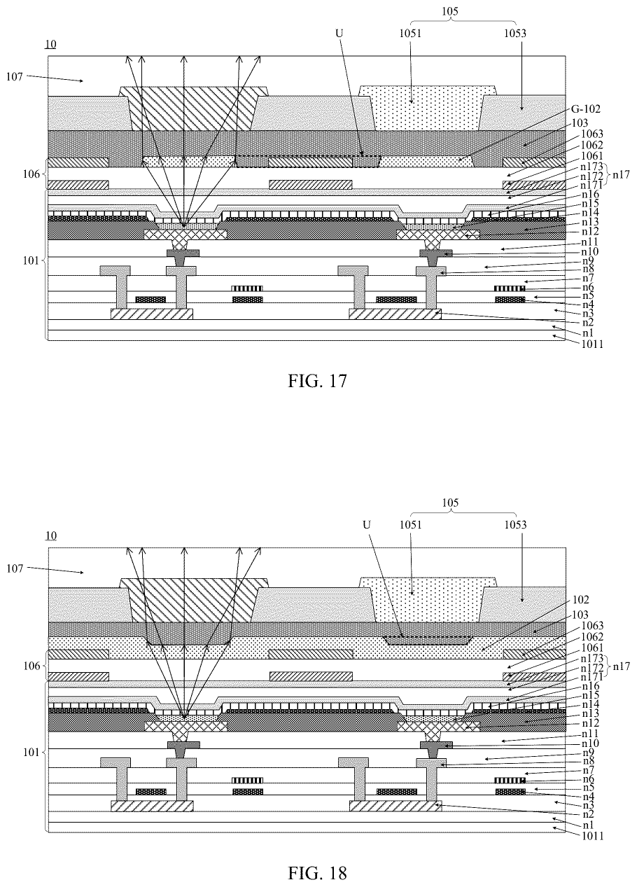

Scheme 2, referring to FIG. 17, the orthographic projection of the groove structure U on the display substrate 101 is within a non-luminous region of the pixel unit 1016. The depth of the groove structure is equal to the thickness of the first dimming layer.

In the embodiments, the first dimming layer 102 includes a plurality of dimming structures G that are spaced apart. The orthographic projection of the dimming structure G on the display substrate 1011 is within the luminous region of the pixel unit 1016. In some embodiments, the side surface of the groove structure U refers to an interface between the groove structure U and the dimming structure G.

Referring to FIG. 17, the dimming structure G is shaped as an approximate trapezoid, and the approximate trapezoid refers to a standard trapezoid or a non-standard trapezoid with a curved surface for process reasons.

Scheme 3, referring to FIG. 18, the orthographic projection of the groove structure U on the display substrate 101 is within the luminous region of the pixel unit 1016. The depth of the groove structure U is less than or equal to the thickness of the first dimming layer 102. It should be noted that FIG. 18 takes the depth of the groove structure U being less than the thickness of the first dimming layer 102 as an example.

Referring to FIG. 18, the groove structure U is shaped as an approximate trapezoid, and the approximate trapezoid refers to a standard trapezoid or a non-standard trapezoid with a curved surface for process reasons.

Referring to FIG. 1, FIG. 3, FIGS. 7 to 14, and FIGS. 17 to 18, the display panel 10 further includes a cover plate 107, wherein the cover plate 107 is disposed on a side, away from the display substrate 101, of the second dimming layer 103. In some embodiments, the cover plate 107 is a glass cover plate.

In some embodiments of the present disclosure, the base substrate 1011 is a glass substrate. Alternatively, the base substrate 1011 is a flexible substrate. Referring to FIG. 1, in the case that the base substrate 1011 is a flexible substrate, the base substrate 1011 includes a first organic layer 10111, a barrier layer 10112, and a second organic layer 10113 that are stacked in sequence, wherein the material of the first organic layer 10111 and the second organic layer 10113 are polyimide (PI) in some embodiments.

The cutting street shown in FIG. 1 is located between the opening region 1011a and the transition region 1011b, and the cutting street refers to a cutting region reserved for cutting to form the opening region 1011a. The cutting street shown in FIG. 11 is located at a side, away from the display region 1011a, of the peripheral region 1011d, and the cutting street refers to a cutting region reserved for cutting to form the edge of the display panel.

In summary, the embodiments of the present disclosure provide a display panel. A display substrate in the display panel includes a base substrate, a plurality of pixel units, a first dimming layer, and a second dimming layer. The refractive index of the first dimming layer is different from the refractive index of the second dimming layer, such that the light rays emitted by the pixel units are converged, a positive light-exiting amount of the pixel unit is increased, and the display effect of the display panel is improved. Further, because a thickness of a portion, within the first target region, of the second dimming layer within the transition region is small, an expansion space is provided for the expansion of the material of the second dimming layer, such that the total expansion amount of the second dimming layer is reduced. As a result, the case of the expansion amount of the second dimming layer being too large is avoided, the warping possibility of the display panel and the peeling possibility of the film layers in the display panel are decreased, and the yield of the display panel is improved.

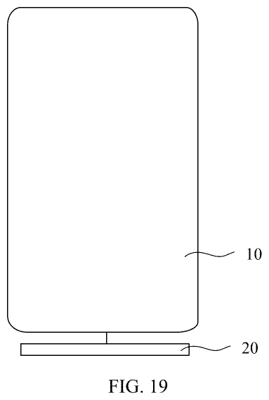

FIG. 19 is a schematic structural diagram of a display device according to some embodiments of the present disclosure. Referring to FIG. 19, in some embodiments, the display device includes: a power supply assembly 20 and the display panel 10 provided by the above embodiments. In some embodiments, the power supply assembly 20 is configured to supply power to the display panel 10.

In some embodiments, the display device is an OLED display device, a quantum dot light-emitting diodes (QLED) display device, an e-paper, a cell phone, a tablet computer, a television set, a monitor, a laptop computer, a digital photo frame, a navigator, or any other product or component having a display function and a fingerprint identification function.

In some embodiments, the display device is an active-matrix organic light-emitting diode (AMOLED) display panel.

Because the display device achieves substantially the same technical effect as the display panel described in the preceding embodiments, the technical effect of the display device is not repeated herein for brevity.

The above descriptions are only some embodiments of the present disclosure and are not intended to limit the present disclosure. Any modifications, equivalent substitutions, improvements, etc. made within the concept and principles of the present disclosure shall fall within the protection scope of the present disclosure.

1. A display panel, comprising a display substrate; wherein the display substrate comprises:
a base substrate, wherein the base substrate comprises an opening region, a transition region surrounding the opening region, a display region surrounding the transition region, and a peripheral region surrounding the display region; and
a plurality of pixel units disposed on a side of the base substrate, wherein the plurality of pixel units are within the display region; and
the display panel further comprising a first dimming layer and a second dimming layer that are disposed on a side, away from the base substrate, of the plurality of pixel units and stacked in sequence;
wherein the first dimming layer and the second dimming layer are disposed in the display region and the transition region, a refractive index of the first dimming layer is different from a refractive index of the second dimming layer, a portion of the second dimming layer within the transition region comprises a plurality of first target regions, and thicknesses of portions of the second dimming layer within the plurality of first target regions are less than a thickness of a portion of the second dimming layer within the transition region other than within the plurality of first target regions.

2. The display panel according to claim 1, wherein structures of the second dimming layer within the plurality of first target regions are grooves or through holes.

3. The display panel according to claim 2, wherein
an orthographic projection of each of the plurality of first target regions on the base substrate is annular, and surrounds the opening region; and
a gap is defined between any two adjacent first target regions of the plurality of first target regions, wherein an orthographic projection of the gap on the base substrate is annular.

4. The display panel according to claim 2, wherein
an orthographic projection of each of the plurality of first target regions on the base substrate is bar-shaped, and each of the plurality of first target regions extends along an arrangement direction of the opening region and the transition region; and
the plurality of first target regions are evenly arranged around the opening region.

5. The display panel according to claim 2, wherein the plurality of first target regions comprise a plurality of first sub-regions and a plurality of second sub-regions; wherein
the plurality of first sub-regions are closer to the opening region relative to the plurality of second sub-regions;
the plurality of first sub-regions are evenly and annularly arranged, and the plurality of first sub-regions are arranged in a direction such that orthographic projections of the plurality of first sub-regions on the base substrate surround the opening region;
the plurality of second sub-regions are evenly and annularly arranged, and the plurality of second sub-regions are arranged in a direction such that orthographic projections of the plurality of second sub-regions on the base substrate surround the orthographic projections of the plurality of first sub-regions on the base substrate; and
the plurality of first sub-regions are staggered with respect to the plurality of second sub-regions.

6. The display panel according to claim 5, wherein the orthographic projections of the plurality of first sub-regions on the base substrate and the orthographic projections of the plurality of second sub-regions on the base substrate are shaped as trapezoids, circles, semicircles, arcs, triangles, rectangles, hexagons, or octagons.

7. The display panel according to claim 1, wherein a plurality of first grooves are defined in a portion of the first dimming layer within the transition region, and at least a portion of the second dimming layer is disposed in the plurality of first grooves.

8. The display panel according to claim 7, wherein the plurality of first grooves are in one-to-one correspondence with the plurality of first target regions, and an orthographic projection of each of the plurality of first grooves on the base substrate is overlapped with an orthographic projection of a corresponding first target region of the plurality of first target regions on the base substrate.

9. The display panel according to claim 7, wherein the plurality of first grooves are staggered with respect to the plurality of first target regions.

10. The display panel according to claim 1, wherein the display panel further comprises a color filter layer disposed on a side, away from the base substrate, of the second dimming layer;
wherein the color filter layer comprises a plurality of color filter blocks disposed in the display region, a plurality of dummy color filter blocks disposed in the transition region, and a black matrix disposed in the display region and the transition region;
wherein the black matrix comprises a plurality of openings, each of the plurality of openings being configured to expose a corresponding color filter block of the plurality of color filter blocks, and an orthographic projection of each of the plurality of color filter blocks covering a luminous region of a corresponding pixel unit of the plurality of pixel units.

11. The display panel according to claim 10, wherein
structures of the second dimming layer within the plurality of first target regions are grooves or through holes; and
at least a portion of the black matrix within the transition region is disposed in the plurality of first target regions.

12. The display panel according to claim 1, wherein the first dimming layer and the second dimming layer are further disposed in the peripheral region; and a portion of the second dimming layer within the peripheral region is provided with a plurality of second target regions, and thicknesses of portions of the second dimming layer within the plurality of second target regions are less than a thickness of a portion of the second dimming layer within the peripheral region other than within the plurality of second target regions.

13. The display panel according to claim 12, wherein structures of the second dimming layer within the plurality of second target regions are grooves or through holes.

14. The display panel according to claim 12, wherein a plurality of second grooves are defined in a portion of the first dimming layer within the peripheral region, and at least a portion of the second dimming layer is disposed in the plurality of second grooves.

15. The display panel according to claim 12, wherein structures of the second dimming layer within the plurality of second target regions are grooves or through holes; and a black matrix in a color filter layer in the display panel is further disposed in the peripheral region;
wherein at least a portion of the black matrix within the peripheral region is disposed in the plurality of second target regions.

16. The display panel according to claim 1, wherein the refractive index of the first dimming layer is less than the refractive index of the second dimming layer; and
a groove structure is defined in a surface, away from the display substrate, of a portion of the first dimming layer within the display region, wherein an angle between an extended surface of a side surface of the groove structure and a bearing surface of the base substrate is an acute angle or an obtuse angle, and a side wall of the groove structure is configured to converge light rays.

17. The display panel according to claim 16, wherein an orthographic projection of the groove structure on the display substrate is within non-luminous regions of the plurality of pixel units; and a depth of the groove structure is less than a thickness of the first dimming layer;
a raised structure is defined on a surface, away from the display substrate, of a portion of the first dimming layer within the display region, an orthographic projection of the raised structure on the display substrate being within luminous regions of the plurality of pixel units; and
the side surface of the groove structure is an interface between the groove structure and the raised structure.

18. The display panel according to claim 16, wherein
an orthographic projection of the groove structure on the display substrate is within non-luminous regions of the plurality of pixel units;
a depth of the groove structure is less than a thickness of the first dimming layer;
the first dimming layer comprises a plurality of dimming structures spaced apart, orthographic projections of the plurality of dimming structures on the display substrate being within the luminous regions of the plurality of pixel units; and
the side surface of the groove structure is an interface between the groove structure and any of the plurality of dimming structures.

19. The display panel according to claim 16, wherein an orthographic projection of the groove structure on the display substrate is within luminous regions of the plurality of pixel units; and a depth of the groove structure is less than or equal to a thickness of the first dimming layer.

20. A display device, comprising: a power supply assembly and a display panel;
wherein the power supply assembly is configured to supply power to the display panel; and
wherein the display panel comprises a display substrate; wherein the display substrate comprises:
a base substrate, wherein the base substrate comprises an opening region, a transition region surrounding the opening region, a display region surrounding the transition region, and a peripheral region surrounding the display region; and
a plurality of pixel units disposed on a side of the base substrate, wherein the plurality of pixel units are within the display region; and
the display panel further comprises a first dimming layer and a second dimming layer that are disposed on a side, away from the base substrate, of the plurality of pixel units and stacked in sequence;
wherein the first dimming layer and the second dimming layer are disposed in the display region and the transition region, a refractive index of the first dimming layer is different from a refractive index of the second dimming layer, a portion of the second dimming layer within the transition region comprises a plurality of first target regions, and thicknesses of portions of the second dimming layer within the plurality of first target regions are less than a thickness of a portion of the second dimming layer within the transition region other than within the plurality of first target regions.
